(19) United States
(12) Patent Application Publication
(10) Pub. No.: US 2010/0126579 A1
(43) Pub. Date: May 27, 2010

(54) SOLAR CELL HAVING REFLECTIVE STRUCTURE

(75) Inventors: Hsuan-Yin Fang, Taichung City (TW); Chao-Hsien Kuo, Hsinchu City (TW); Chian-Fu Huang, Keelung City (TW)

Correspondence Address: J C PATENTS, 4 VENTURE, SUITE 250, IRVINE, CA, 92618, US

(73) Assignee: INDUSTRIAL TECHNOLOGY RESEARCH INSTITUTE, Hsinchu (TW)

(21) Appl. No.: 12/563,348

(22) Filed: Sep. 21, 2009

(30) Foreign Application Priority Data
Nov. 21, 2008 (TW) 97145207

(51) Int. Cl. H01L 31/00

(52) U.S. Cl. 136/256

(57) ABSTRACT

A solar cell having a reflective structure is provided, which includes a front contact, a P layer, an I layer, an N layer, and a back contact that are stacked together. The solar cell having the reflective structure is characterized in that the N layer is a layer of low refraction index, and a refraction index of the layer of low refraction index is lower than that of the I layer. Furthermore, the N layer may be a multi-layer structure consisting of several films in which films with low refraction indexes and films with high refraction indexes are stacked alternately. The film in contact with the I layer in the multi-layer structure is a film of low refraction index. A refraction index of the film of low refraction index is lower than that of the I layer.

### CROSS-REFERENCE TO RELATED APPLICATION

This application claims the priority benefit of Taiwan application serial no. 97145207, filed on Nov. 21, 2008. The entirety of the above-mentioned patent application is hereby incorporated by reference herein and made a part of this specification.

### BACKGROUND OF THE INVENTION

1. Field of the Invention

The present invention relates to a solar cell having a reflective structure.

2. Description of Related Art

The solar energy is a non-polluting and inexhaustible energy source. When petrochemical energy sources confront with problems such as pollution and shortage, the mass has gradually focused on the issue of how to utilize the solar energy source efficiently. As solar cells can convert solar energy into electric energy directly, the solar cells have become a key point currently in terms of utilizing the solar energy.

However, the current amorphous silicon (a-Si) film products used in a solar cell have two problems. One is irradiation stability and the other is that only the sunlight with a wavelength less than 800 nm can be absorbed.

Therefore, other methods capable of enhancing the utilization efficiency are required. Currently, it is believed that the most preferred solution for enhancing the efficiency lies in decreasing a thickness of a hydrogenated amorphous silicon (a-Si:H) photoelectric conversion layer and staking micro-crystalline (μc-Si) film solar cells capable of absorbing lights with a long wavelength into a tandem solar cell.

Accordingly, it can lower the light absorbance to decrease a thickness of the photoelectric conversion layer. However, as for a conventional tandem solar cell, since the refraction index coefficients of both cells are quite close and both of the cells are silicon layers with a refraction index of about 4, no reflective interface will be formed when light passes through an interface between the two cells, and only when the light reaches a silver layer, the light is reflected to a μc-Si layer of a bottom cell.

### SUMMARY OF THE INVENTION

Accordingly, the present invention is directed to a solar cell having a reflective structure, which can reflect lights directly to an amorphous silicon (a-Si) layer, thereby decreasing a thickness of a photoelectric conversion layer.

The present invention is further directed to a solar cell having a reflective structure, which can increase a light flux and absorption of a photoelectric conversion layer, so as to increase a short circuit current density (Jsc).

As embodied and broadly described herein, the present invention provides a solar cell having a reflective structure, which includes a front contact, a P layer, an intrinsic layer (I layer), an N layer, and a back contact that are stacked together. The solar cell is characterized in that the N layer is a layer of low refraction index, and a refraction index of the layer of low refraction index is lower than that of the I layer.

The present invention further provides a solar cell having a reflective structure, which includes a front contact, a P layer, an I layer, an N layer, and a back contact that are stacked together. The solar cell having the reflective structure is characterized in that the N layer is a multi-layer structure formed by several films in such a manner that films with low refraction indexes and films with high refraction indexes are stacked alternately. In the multi-layer structure, a film in contact with the I layer is a film of low refraction index. A refraction index of the film of low refraction index is lower than that of the I layer.

Based on the above, the present invention provides an N layer of low refraction index in a solar cell structure, which can increase the reflection of an interface, decrease the thickness of an I layer in an a-Si solar cell, achieve the highest utilization efficiency of the sunlight, thereby increasing a Jsc and enhancing the element efficiency.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a solar cell having a reflective structure according to a first embodiment of the present invention.

FIG. 2 is a schematic cross-sectional view of a solar cell having a reflective structure according to a second embodiment of the present invention.

FIG. 3 is a schematic cross-sectional view of a solar cell having a reflective structure according to a third embodiment of the present invention.

FIG. 4 is a schematic cross-sectional view of a solar cell having a reflective structure according to a fourth embodiment of the present invention.

FIG. 5 is a curve diagram of refraction indexes of N—SiOx, N-a-Si:H, and N-μc-Si:H changing with wavelengths.

FIG. 6 is a curve diagram of extinction coefficients of N—SiOx, N-a-Si:H, and N-μc-Si:H changing with wavelengths.

FIG. 7 is a curve diagram of a reflectivity of an N layer of the present invention and that of a conventional N layer changing with wavelengths.

FIG. 8 is a curve diagram of a QE of a solar cell in the present invention and that of a conventional single junction solar cell changing with wavelengths.

FIG. 9 is a curve diagram of QEs of Example 1, Example 2, and a contrast example of the present invention changing with wavelengths.

FIG. 10A is a curve diagram of a QE of the contrast example in FIG. 9 changing with wavelengths.

FIG. 10B is a curve diagram of a QE of a tandem solar cell having a layer of low refraction index in Experiment 5 changing with wavelengths.

FIG. 10C is a curve diagram of a QE of a tandem solar cell having a multi-layer structure with a reflection effect in Experiment 5 changing with wavelengths.

FIG. 11 is a Nano beam diffraction Pattern of N—SiOx Layer.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

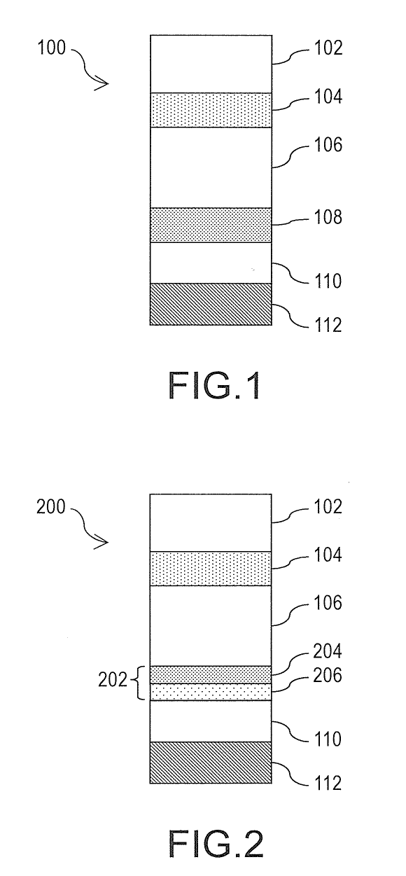

FIG. 1 is a schematic cross-sectional view of a solar cell having a reflective structure according to a first embodiment of the present invention.

Referring to FIG. 1, a solar cell 100 having a reflective structure in the first embodiment includes a front contact 102, a P layer 104, an intrinsic layer (I layer) 106, a layer of low refraction index 108 to serve as an N layer, and a back contact 110. A refraction index of the layer of low refraction index 108 is lower than that of the I layer 106. Moreover, a difference between the refraction index of the layer of low refraction index 108 and that of the I layer 106 is, for example, greater than or equal to 1.5. In the first embodiment, the refraction index of the layer of low refraction index 108 is, for example, less than or equal to 2.1, and a thickness thereof is about less than 150 nm. The layer of low refraction index 108 may be made of a material selected from a group consisting of N type silicon oxide (N—SiOx), N type silicon carbide (N—SiCx), N type silicon nitride (N—SiNx), N type amorphous silicon (N-a-Si), and N type micro-crystalline silicon (N-μc-Si). For example, when the layer of low refraction index 108 is N type silicon oxide (N—SiOx) layer, an electrical conductivity of the layer of low refraction index 108 is at least greater than 10⁻⁷ S/cm. In addition, a metal layer 112, for example, silver, is generally disposed on a back surface of the back contact 110.

As the layer of low refraction index 108 in the first embodiment can reflect lights back to the I layer 106, a light gain of the lights reflected back to the I layer 106 is further utilized, so that the I layer 106 further absorbs the lights with a waveband in the visible region once again, so as to generate more photoelectric current. In addition, the layer of low refraction index 108 is, for example, microcrystalline structure.

FIG. 2 is a schematic cross-sectional view of a solar cell having a reflective structure according to a second embodiment of the present invention. Reference numbers the same as those of FIG. 1 are used in FIG. 2 to refer to the same elements.

Referring to FIG. 2, a solar cell 200 having a reflective structure in the second embodiment includes a front contact 102, a P layer 104, an I layer 106, a multi-layer structure 202 to serve as an N layer, and a back contact 110. The multi-layer structure 202 is formed by several films in such a manner that films with low refraction indexes and films with high refraction indexes are stacked alternately. Furthermore, a film in contact with the I layer 106 in the multi-layer structure 202 is a film of low refraction index 204. The refraction index of the film of low refraction index 204 is lower than that of the I layer 106. The difference between the refraction index of the film of low refraction index 204 and that of the I layer 106 is, for example, greater than or equal to 1.5. In the second embodiment, the refraction index of the film of low refraction index 204 is, for example, less than or equal to 2.1. A material of the film of low refraction index 204 may be obtained with reference to the material of the layer of low refraction index 108 in the first embodiment. For example, when the film of low refraction index 204 is an N—SiOx layer, the electrical conductivity of the film of low refraction index 204 is at least greater than 10⁻⁷ S/cm. Additionally, the layer of low refraction index 204 is, for example, microcrystalline structure. In the multi-layer structure 202, a film in contact with the back contact 110 is a film of high refraction index 206. The refraction index of the film of high refraction index 206 is generally greater than that of the back contact 110, so that the film of high refraction index 206 may be selected to be made of an N type hydrogenated amorphous silicon (N-a-Si:H) that serves as an N layer in the prior art. In addition, the difference between the refraction index of the film of low refraction index 204 and that of the film of high refraction index 206 is, for example, greater than or equal to 1.5.

In the second embodiment, since reflective interfaces in multiple layers are provided (for example, an interface between the I layer 106 and the film of low refraction index 204, an interface between the film of low refraction index 204 and the film of high refraction index 206, and an interface between the film of high refraction index 206 and the back contact 110), a light flux and absorption of a photoelectric conversion layer can be increased, thereby increasing the Jsc.

Although the multi-layer structure 202 in FIG. 2 only has one film of low refraction index 204 and one film of high refraction index 206, the number of films in the multi-layer structure 202 may still be increased depending on the design requirements. However, the thickness of the multi-layer structure 202 is preferably less than 150 nm. A metal layer 112 is generally disposed on a back surface of the back contact 110.

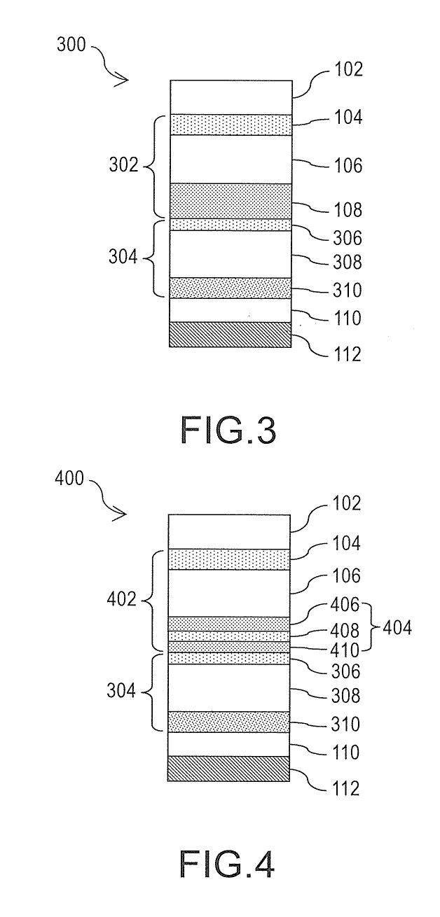

FIG. 3 is a schematic cross-sectional view of a solar cell having a reflective structure according to a third embodiment of the present invention. Reference numbers the same as those of FIG. 1 are used in FIG. 3 to refer to the same elements.

Referring to FIG. 3, a solar cell 300 having a reflective structure in the third embodiment is a tandem solar cell. The tandem solar cell has a set of top cells 302 and a set of bottom cells 304. Each of the top cells 302 in the tandem solar cell includes a P layer 104, an I layer 106, and a layer of low refraction index 108 to serve as an N layer that are stacked together as that mentioned in the first embodiment. Each of the bottom cells 304 includes a bottom cell P layer 306, a bottom cell I layer 308, and a bottom cell N layer 310 that are stacked together. The bottom cell P layer 306 of the bottom cell 304 is in contact with the layer of low refraction index 108 of the top cell 302. A back contact 110 is disposed on a back surface of the bottom cell N layer 310 of the bottom cell 304, and furthermore, the metal layer 112 is generally disposed on the back surface of the back contact 110.

The layer of low refraction index 108 in the third embodiment can reflect lights back to the I layer 106, so as to prevent an N/P layer in a conventional tandem solar cell with an intermediate layer from absorbing the reflective lights once again. Moreover, with the layer of low refraction index 108 having a reflective function, the intermediate layer in the conventional tandem solar cell can be omitted.

FIG. 4 is a schematic cross-sectional view of a solar cell having a reflective structure according to a fourth embodiment of the present invention. Reference numbers the same as those of FIG. 3 are used in FIG. 4 to refer to the same elements.

Referring to FIG. 4, a solar cell 400 having a reflective structure in the fourth embodiment is also a tandem solar cell, which includes a set of top cells 402 and a set of bottom cells 304. Each of the bottom cells 304 includes a bottom cell P layer 306, a bottom cell I layer 308, and a bottom cell N layer 310 that are stacked together as mentioned in the third embodiment. Each of the top cells 402 includes a P layer 104, an I layer 106, and a multi-layer structure 404 to serve as an N layer that are stacked together as mentioned in the first embodiment. The multi-layer structure 404 is formed by several films in such a manner that films with low refraction indexes and films with high refraction indexes are stacked alternately. In the multi-layer structure 404, a film in contact with the I layer 106 is a film of low refraction index 406, and then a layer of high refraction index 408 and another film of low refraction index 410 are further stacked. The refraction indexes of the films of low refraction index 406 and 410 are lower than that of the I layer 106, the bottom cell P layer 306, and the film of high refraction index 408 respectively. In the embodiment, the difference between the refraction indexes of the films of low refraction index 406 and 410 and that of the I layer 106 and the film of high refraction index 408 are greater than or equal to 1.5.

In the fourth embodiment, the refraction indexes of the films of low refraction index 406 and 410 are, for example, less than or equal to 2.1. The film of high refraction index 408 may be selected to be made of a material for an N layer in the prior art. In other words, in the multi-layer structure 404, materials of the films stacked alternately may be selected from a group consisting of N—SiOx, N—SiCx, N—SiNx, N-a-Si, and N-μc-Si. For example, when the films of low refraction index 406 and 410 are N—SiOx layers, the electrical conductivity of the films of low refraction index 406 and 410 is at least greater than 10⁻⁷ S/cm. The film of high refraction index 408 may be an N-a-Si layer, and the electrical conductivity thereof is about 10⁻⁴ S/cm. Each layer in the multi-layer structure 404 is completed in the same manufacturing process.

In the fourth embodiment, since reflective interfaces in multiple layers (such as an interface between the I layer 106 and the film of low refraction index 406, an interface between the film of low refraction index 406 and the film of high refraction index 408, an interface between the film of high refraction index 408 and the film of low refraction index 410, and an interface between the film of low refraction index 410 and the bottom cell P layer 306) are provided, the light flux and absorption of the photoelectric conversion layer can be increased, thereby increasing the Jsc. In addition, at least one of the films of low refraction index 406 and 410 is microcrystalline structure, for example. Although the multi-layer structure 404 in FIG. 4 is formed by two films of low refraction index 406, 410 and one film of high refraction index 408 and serves as an N layer, the number of films in the multi-layer structure 404 may still be increased depending on the design requirements. However, the total thickness of the multi-layer structure 404 is preferably less than 150 nm.

Several experiments are listed below to demonstrate the efficacies of the present invention.

### Experiment 1

In order to prove that the demonstrative N—SiOx in each of the above embodiments of the present invention is a suitable material with a low refraction index, the N—SiOx is compared with a conventional N layer material used in a top cell of a tandem solar cell, that is, N type hydrogenated amorphous silicon (N-a-Si:H), and a conventional N layer material used in a bottom cell of a tandem solar cell, that is, N type micro-crystalline silicon (N-μc-Si:H).

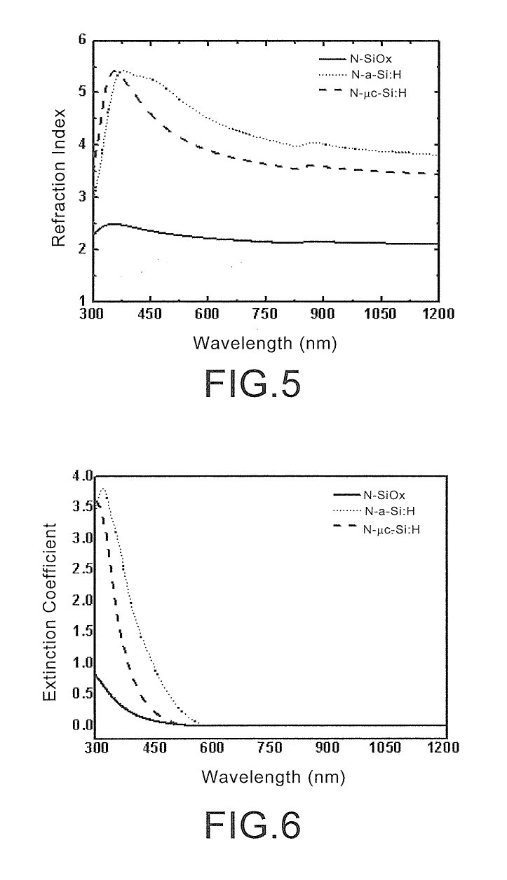

As seen from the curve diagram (shown in FIG. 5) of refraction indexes of the N—SiOx, N-a-Si:H, and N-μc-Si:H changing with wavelengths, a refraction index of the demonstrative N—SiOx in each embodiment of the present invention is lower than that of the N-a-Si:H and the Nᵢ μc-Si:H.

As seen from the curve diagram (shown in FIG. 6) of extinction coefficients of the N—SiOx, N-a-Si:H, and N-μc-Si:H changing with wavelengths, an extinction coefficient of the demonstrative N—SiOx in each embodiment of the present invention is also lower than that of the N-a-Si:H and the N-μc-Si:H.

### Experiment 2

In order to prove that the N layer of the present invention further contributes to increasing the light reflection, a glass of 1.1 mm is used as a substrate. An a-Si (n=4) of 300 nm is stacked on the substrate as an I layer, and then micro-crystalline SiOx (n=2.1) of 100 nm with a low refraction index is stacked on the I layer as an N layer of the present invention.

In addition, a contrast example is manufactured. In the same way as that described above, a glass of 1.1 mm is used as a substrate. An a-Si (n=4.5) of 300 nm is stacked on the substrate as an I layer. Difference from the above manner, a μc-Si of 30 nm is then stacked on the I layer as a conventional N layer.

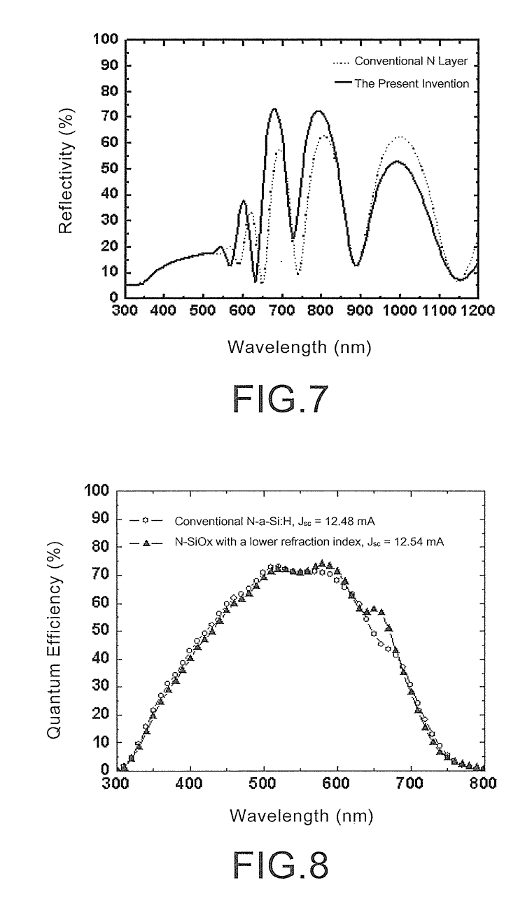

Subsequently, lights with different wavelengths are irradiated from the glass towards the N layer, and then, the reflectivity of the N layers is measured and shown in FIG. 7. From FIG. 7, it can be seen that the reflectivity of the N layer at wavelengths between 550 nm and 800 nm is significantly greater than that of the conventional N layer, so that the film of low refraction index of the present invention is capable of increasing the light reflection.

### Experiment 3

In order to compare the Jsc of the present invention with that of a conventional single junction solar cell, first of all, a solar cell with a layer of low refraction index of the present invention is manufactured. The solar cell includes a TCO as a front contact, a P layer of 100 nm, an I layer (n=4) of 350 nm, an N—SiOx layer (n=2) of 100 nm with a low refraction index as an N layer of the present invention, a TCO as a back contact, and a silver layer.

In addition, a contrast example is manufactured. The only difference between the contrast example and the above solar cell lies in that an a-Si (n=4.5) of 30 nm is used as a conventional N layer.

Then, lights of different wavelengths are irradiated from the front contact into the solar cells, and then, the quantum efficiency (QE) of the N layers is measured and shown in FIG. 8. As seen from FIG. 8, when the conventional N layer in the solar cell is replaced with the N—SiOx layer of low refraction index, the QE is increased in wavelengths between 550 nm and 750 nm, and thus the Jsc is increased by 0.5%.

### Experiment 4

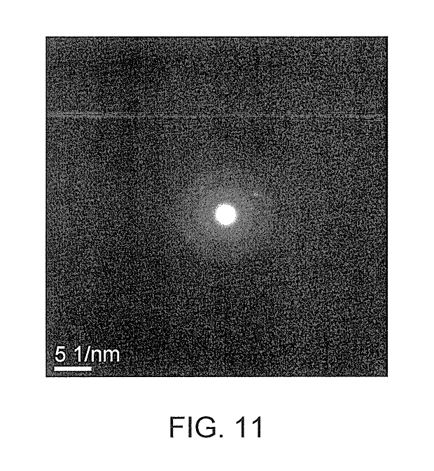

In order to compare the Jsc of a tandem solar cell of the present invention with that of a conventional tandem solar cell, first of all, the tandem solar cell (Example 1) with a layer of low refraction index of the present invention is designed, which includes: a TCO as a front contact; a top cell containing a P layer of 10 nm, an I layer (n=4) of 280 nm, and an N—SiOx layer (n=2) of 44 nm with a low refraction index; a bottom cell containing a P layer of 10 nm, a μc-Si of 3 μm as an I layer, and a conventional N layer of 20 nm; a TCO as a back contact; and a silver layer. Herein, the N—SiOx layer is microcrystalline structure as show in nano beam diffi action (NBD) pattern of FIG. 11.

In addition, a tandem solar cell (Example 2) having a multi-layer structure with a reflective effect of the present invention is designed. The difference between Example 2 and Example 1 lies in that, the N layer of the top cell is replaced with a multi-layer structure formed by an N—SiOx layer (n=2) of 55 nm, an N-a-Si layer (n=4.5) of 27.5 nm, and an N—SiOx layer (n=2) of 55 nm which contains microcrystalline structure, and the I layer of the bottom cell is replaced with a μc-Si of 4 μm.

The corresponding contrast example includes a TCO as a front contact; a top cell containing a P layer of 10 nm, an I layer (n=4) of 280 nm, and a conventional N layer (amorphous silicon, n=4) of 30 nm; a bottom cell containing a P layer of 10 nm, a μc-Si of 2 μm as an I layer, and a conventional N layer of 20 nm; a TCO as a back contact; and a silver layer.

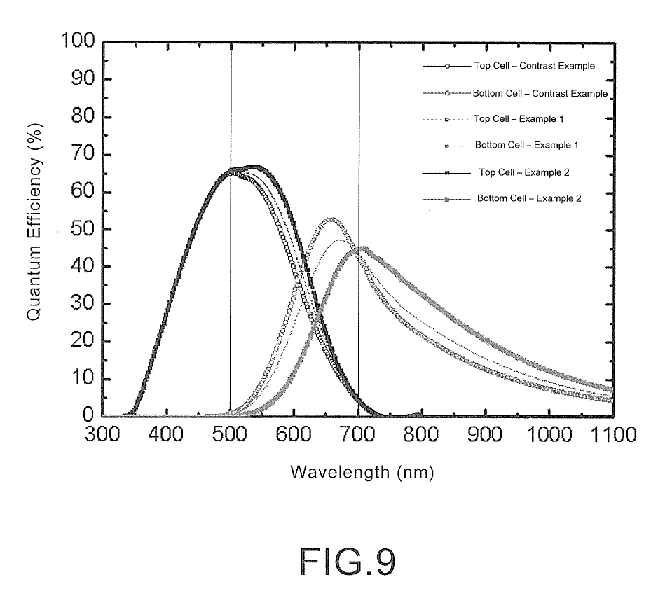

Then, lights of different wavelengths are simulated to be irradiated from the front contact into the tandem solar cell, and then the quantum efficiency (QE) is measured and shown in FIG. 9. As seen from FIG. 9 that, in the tandem solar cell, compared with the contrast example, Example 1 achieves a significant increase of the light reflection at the wavelengths between 500 nm and 700 nm, and meanwhile, the QE of the top cell increases and the QE of the bottom cell decreases. As for Example 2 with a fixed thickness of the I layer of the top cell, the Jsc of the top cell increases from 8.05 mA/cm² to 8.87 mA/cm², that is, the Jsc is increased by 10%. Meanwhile, the thickness of the I layer of the bottom cell is increased by about 50%, and a current match between the top cell and the bottom cell is achieved.

### Experiment 5

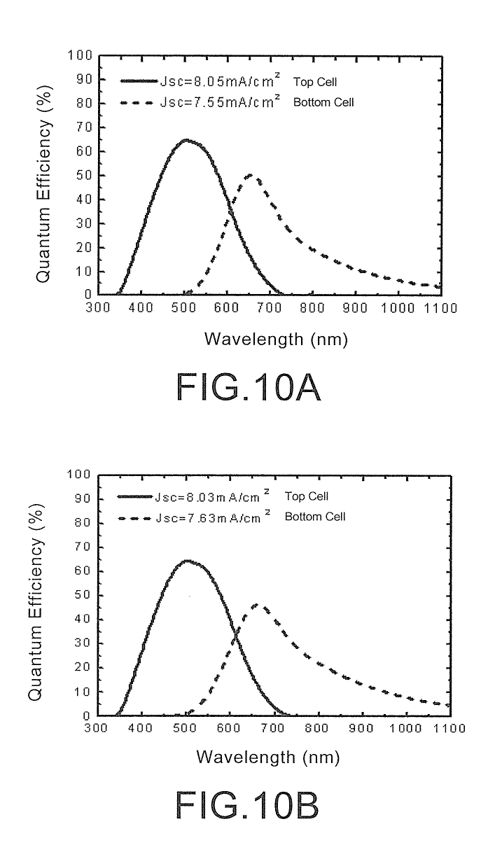

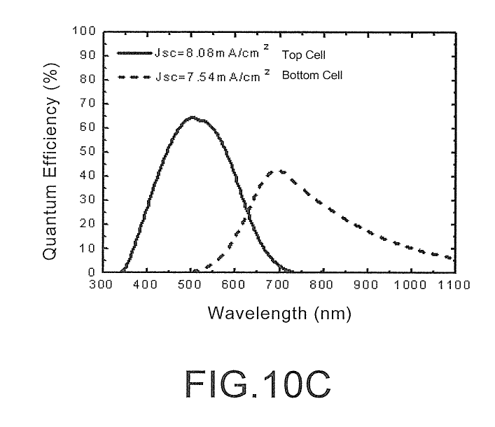

In order to further illustrate the thickness changes of an I layer in a bottom cell and a top cell, a curve diagram of QE variation is obtained and shown in FIG. 10A through simulation based on the contrast example in Experiment 4.

Then, a tandem solar cell having a layer of low refraction index is designed, which includes a TCO as a front contact; a top cell containing a P layer of 10 nm, an I layer (n=4) of 230 nm and an N—SiOx layer (n=2) of low refraction index of 44 nm; a bottom cell containing a P layer of 10 nm, a μc-Si of 2.5 μm as an I layer, and a conventional N layer of 20 nm; a TCO as a back contact; and a silver layer. Herein, the N—SiOx layer is microcrystalline structure as show in FIG. 11. Subsequently, a curve diagram of the QE variation is obtained and shown in FIG. 10B through simulation.

Then, a tandem solar cell having a multi-layer structure with a reflective effect is designed. The differences between the tandem solar cell and Example 1 lie in that, the thickness of the I layer in the top cell is reduced to 190 nm; the N layer is replaced with a multi-layer structure containing an N—SiOx layer (n=2) of 55 nm, an N-a-Si layer (n=4.5) of 27.5 nm, and an N—SiOx layer (n=2) of 55 nm; the thickness of the I layer in the bottom cell is changed to 3.3 μm. Herein, the N—SiOx layer is microcrystalline structure as show in FIG. 11. Subsequently, a curve diagram of the QE variation is obtained and shown in FIG. 10C through simulation.

In the tandem solar cell, the N layer is designed into a multi-layer structure, and the current of the top cell is fixed. The thickness of the I layer in the top cell may be decreased by 32%. As long as the thickness of the I layer in the bottom cell is increased by about 39%, a current match between the top cell and the bottom cell can be achieved.

As known from Experiment 4 and Experiment 5, the light deterioration can be alleviated by means of fixing the current of the top cell and reducing the thickness of the top cell (Staebler Wronski Effect, briefly referred to as SWE effect). Meanwhile, a fill factor may be added, and the thickness increment of the bottom cell may be reduced. Thus, it is a more preferable manner to fix the current of the top cell and reduce the thickness of the top cell than that of fixing the thickness of the top cell.

To sum up, the present invention has an N layer with reflection and conductivity functions, which is capable of reflecting lights back to the I layer, and utilizing the gain of the lights reflected to the I layer to enable the amorphous silicon film to absorb the lights with wavelengths in the visible region once again, so as to reduce the thickness of the I layer while achieving the same efficiency as a thicker one. Alternatively, an I layer with the same thickness can be employed, and the N layer film with reflection and conductivity functions of the present invention can produce more photoelectric current. Moreover, when the present invention is applied to a tandem solar cell, an N layer with reflection and conductivity functions can be employed to design a single-layer or multi-layer structure in the top cell. The reflection at the designed structure interfaces can be utilized to increase the light flux and absorption of the photoelectric conversion layer, thereby increasing the Jsc.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar cell having a reflective structure, comprising: a front contact, a P layer, an I (intrinsic) layer, an N layer, and a back contact that are stacked together, wherein:
the N layer is a layer of low refraction index, and a refraction index of the layer of low refraction index is lower than that of the I layer.

2. The solar cell having a reflective structure according to claim 1, wherein a difference between the refraction index of the layer of low refraction index and that of the I layer in contact with the layer of low refraction index is greater than or equal to 1.5.

3. The solar cell having a reflective structure according to claim 1, wherein a thickness of the layer of low refraction index is less than 150 nm.

4. The solar cell having a reflective structure according to claim 1, wherein the layer of low refraction index is made of N type silicon oxide (N—SiOx), N type silicon carbide (N—SiCx), N type silicon nitride (N—SiNx), N type amorphous silicon (N-a-Si), or N type micro-crystalline silicon (N-μc-Si).

5. The solar cell having a reflective structure according to claim 1, wherein when the layer of low refraction index is an N type silicon oxide (N—SiOx) layer, an electrical conductivity of the N—SiOx layer is greater than 10⁻⁷ S/cm.

6. The solar cell having a reflective structure according to claim 1, further comprising: a set of bottom cells located between the N layer and the back contact, wherein each of the bottom cells comprises a bottom cell P layer, a bottom cell I layer, and a bottom cell N layer that are stacked together, and the layer of low refraction index comprises microcrystalline structure.

7. The solar cell having a reflective structure according to claim 6, wherein the refraction index of the layer of low refraction index is lower than that of the bottom cell P layer.

8. A solar cell having a reflective structure, comprising: a front contact, a P layer, an I (intrinsic) layer, an N layer, and a back contact that are stacked together, wherein:
the N layer is a multi-layer structure formed by a plurality of films in such a manner that films with low refraction indexes and films with high refraction indexes are stacked alternately, and a film in contact with the I layer in the multi-layer structure is a film of low refraction index, and a refraction index of the film of low refraction index is lower than that of the I layer.

9. The solar cell having a reflective structure according to claim 8, wherein a difference between the refraction index of the film of low refraction index and that of the I layer in contact with the film of low refraction index is greater than or equal to 1.5.

10. The solar cell having a reflective structure according to claim 8, wherein a thickness of the multi-layer structure is less than 150 nm.

11. The solar cell having a reflective structure according to claim 8, wherein the film of low refraction index is made of N type silicon oxide (N—SiOx), N type silicon carbide (N—SiCx), N type silicon nitride (N—SiNx), N type amorphous silicon (N-a-Si), or N type micro-crystalline silicon (N-μc-Si).

12. The solar cell having a reflective structure according to claim 8, wherein when the film of low refraction index is an N type silicon oxide (N—SiOx) layer, an electrical conductivity of the N—SiOx layer is greater than 10⁻⁷ S/cm.

13. The solar cell having a reflective structure according to claim 8, wherein a film in contact with the back contact in the multi-layer structure is a film of high refraction index, and a refraction index of the film of high refraction index is greater than that of the back contact.

14. The solar cell having a reflective structure according to claim 13, wherein a difference between the refraction index of the film of low refraction index and that of the film of high refraction index is greater than or equal to 1.5.

15. The solar cell having a reflective structure according to claim 8, further comprising a bottom cell located between the N layer and the back contact, wherein the bottom cell comprises a bottom cell P layer, a bottom cell I layer, and a bottom cell N layer, and the film of low refraction index comprises microcrystalline structure.

16. The solar cell having a reflective structure according to claim 15, wherein the multi-layer structure comprises the film of low refraction index, the film of high refraction index, and another film of low refraction index that are stacked together.

17. The solar cell having a reflective structure according to claim 16, wherein a refraction index of the another film of low refraction index is lower than that of the bottom cell P layer.
